(19) United States
(12) Patent Application Publication
(10) Pub. No.: US 2013/0285118 A1
(43) Pub. Date: Oct. 31, 2013

(54) CMOS WITH SiGe CHANNEL PFETs AND METHOD OF FABRICATION

(71) Applicants: Amlan Majumdar, White Plains, NY (US); Zhibin Ren, Hopewell Junction, NY (US)

(72) Inventors: Amlan Majumdar, White Plains, NY (US); Zhibin Ren, Hopewell Junction, NY (US)

(73) Assignee: International Business Machines Corporation, Armonk, NY (US)

(21) Appl. No.: 13/612,115

(22) Filed: Sep. 12, 2012

Related U.S. Application Data
(62) Division of application No. 13/457,847, filed on Apr. 27, 2012.

(51) Int. Cl. H01L 27/092

(52) U.S. Cl. 257/192; 257/E27.062

(57) ABSTRACT

A thin-body SOI CMOS structure and method for fabricating thin-body SOI CMOS structures with Si channels for NFETs and SiGe/Si or SiGe channels for PFETs. The CMOS structure imparts beneficial channel stress to PFETs while not degrading NFETs and leading to beneficial higher gate capacitance for PFETs.

### CROSS REFERENCE TO RELATED APPLICATION

This application is a divisional of co-pending application Ser. No. 13/457,847, filed on Apr. 27, 2012, and for which priority is claimed under 35 U.S.C. §120; the entire contents of which is are hereby incorporated by reference.

### TECHNICAL FIELD

The present disclosure is generally related to complementary metal-oxide-semiconductor field-effect transistors, and more particularly, to thin-body fully-depleted SOT FETs with SiGe in the channel region of PFETs.

### BACKGROUND OF THE DISCLOSURE

Complementary metal-oxide semiconductor (“CMOS”) field-effect transistors (“FETs”) are employed in almost every electronic circuit application, such as signal processing, computing, and wireless communications. CMOS chips in manufacturing comprise planar thick-body devices on bulk Si substrates or silicon-on-insulator (“SOT”) substrates. Thick-body FETs on SOT substrates are also referred to as partially-depleted SOT (“PDSOI”) FETs. In modern CMOS circuits/chips comprising either bulk Si or PDSOI FETs, embedded SiGe source/drain (“SD”) is used in p-channel FETs (“PFETs”) for obtaining uniaxial compressive stress in the channel for mobility and performance enhancement.

Scaling down the gate length of both n-channel FETs (“NFETs”) and PFETs in CMOS circuits to shorter dimensions leads to increased CMOS circuit speed. However, detrimental short-channel effects also lead to high off-state leakage currents in CMOS devices, thereby increasing power consumption. In case of extreme short-channel effects, CMOS circuits fail to operate.

Narrow-body planar and non-planar FETs, such as extremely-thin SOI (“ETSOI”) FETs, FinFETs, and trigates, exhibit significantly superior short-channel characteristics compared to thick-body bulk Si and PDSOI FETs. These FET architectures are, therefore, very attractive candidates for future-generation CMOS technology. The effectiveness of embedded SiGe SD in a thin-body SOI is greatly reduced due to the lack of recess depth on thin SOI substrates. Therefore, the performance of thin-body PFETs is degraded compared to those of thick-body PFETs.

Biaxial compressive stress can also lead to improvement in PFET mobility and performance. High-performance p-channel modulation-doped FETs (MODFETs) with SiGe channel have been demonstrated. It is also well known in the art than NFET performance is enhanced with tensile stress in the channel and degraded with compressive stress in the channel. Therefore, it is beneficial to create ETSOI CMOS with Si channel NFETs and SiGe in the PFET channel.

U.S. Pat. No. 5,461,250 (Burghartz, et al.) describes dual gate thin SOI p-channel MOSFET structures with one or more relatively thin layers of SiGe sandwiched between layers of Si. The SiGe and Si layers are formed on an insulating substrate and are doped to form a source and a drain region to thereby define a channel region. The SiGe layer(s) are pseudomorphically grown on the Si and are therefore placed under compressive strain. If one were to fabricate CMOS with both NFETs and PFETs on the layers according to Burghartz, et al., the NFET performance would be degraded due to the presence of compressive stress.

U.S. Pat. Nos. 6,900,502 (Ge, et al.) and 7,138,310 (Currie, et al.) each describe SOI CMOS with tensile Si layered with compressive SiGe formed on bulk substrates. Such structures are favorable for NFETs due to the presence of tensile stress in the surface Si channel. However, the structures are not favorable for fabricating surface-channel P-MOSFETs because tensile stress lowers the hole mobility, thereby reducing PFET drive currents. For example, the tensile-Si layer of the structure of Currie, et al. acts like a gate dielectric and severely reduces gate capacitance, which leads to worse short-channel effects because of the less fate control on the channel and also lower drive currents because of reduced gate capacitance. Thus, PFETs in the structure described by Currie, et al. will not only have higher off-state current due to worse short-channel effects but also will have lower on-state current due to reduced gate capacitance.

Accordingly, a CMOS structure with favorable channel materials for both NFETs and PFETs and method for forming such a structure is desired.

### SUMMARY OF THE DISCLOSURE

Thin-body SOI CMOS structures with Si channels for NFETs, and SiGe/Si or SiGe channels for PFETs and preferably high-K/metal gate stack are disclosed. This CMOS structure imparts beneficial channel stress to PFETs without degrading NFETs. Furthermore, use of high-K as a gate dielectric alleviates the problem of SiGe not forming a high-quality oxide.

More particularly, the present disclosure relates to a method of fabricating CMOS structure substrates comprising:

(a) providing SOI wafer;

(b) oxidizing the wafer;

(c) depositing a layer of nitride;

(d) creating global alignment markers on the SOI region;

(e) selectively opening PFET regions in the resist;

(f) exposing the SOI in the PFET regions;

(g) resist stripping the exposed SOI in the PFET regions;

(h) selectively thinning the PFET regions;

(i) selectively depositing SiGe on the exposed SOI in the PFET regions; and

(j) removing the layers of nitride and oxide from the NFET regions.

Further, the present disclosure relates to a CMOS structure comprising:
(A) a NFET channel, wherein the NFET channel material comprises Si;
(B) a PFET channel, wherein the PFET channel material comprises a bottom layer of SiGe and a top layer of Si; and
(C) a buried oxide layer, wherein the buried oxide layer is underneath both the NFET channel and PFET channel.

Still other objects and advantages of the present disclosure will become readily apparent by those skilled in the art from the following detailed description, where it is shown and described only the preferred embodiment(s), simply by way of illustration of the best mode. As will be realized, the disclosure is capable of other and different embodiments, and its several details are capable of modification in various obvious respects, without departing from the disclosure. Accordingly, the description is to be regarded as illustrative in nature and not as restrictive.

### BRIEF DESCRIPTION OF THE DRAWINGS

FIG. 1 is a cross-sectional view of an embodiment of the substrate of the present invention with pad nitride and pad oxide.

FIG. 2 is a top-down schematic representation of an embodiment of the present invention depicting the wafer after alignment marker creation.

FIG. 3 is a cross-sectional view of an embodiment of the present invention where nitride/oxide RIE was performed to expose the SOI in the PFET region followed by resist stripping.

FIG. 4 is a cross-sectional view of an embodiment of the present invention depicting the thinned SOI in the PFET region.

FIG. 5 is a cross-sectional view of an embodiment of the present invention depicting SiGe deposited on the exposed SOI in the PFET region.

FIG. 6 is a cross-sectional view of an embodiment of the present invention depicting nitride-oxide layers removed from the NFET region.

FIG. 7 is a cross-sectional view of an embodiment of the CMOS structure of the present disclosure.

### DESCRIPTIONS OF THE VARIOUS EMBODIMENTS OF THE DISCLOSURE

The present disclosure, which is directed to novel CMOS structures with favorable channel materials for both NFETs and PFETs, and a method of fabricating these devices, will now be described in greater detail by referring to the drawings that accompany the present application. It is noted that in the accompanying drawings, like reference numerals are used for describing like and/or corresponding elements.

The term “comprising” (and its grammatical variations) as used herein is used in the inclusive sense of “having” or “including” and not in the exclusive sense of “consisting only of.” The terms “a” and “the” are used herein are understood to encompass the plural as well as the singular.

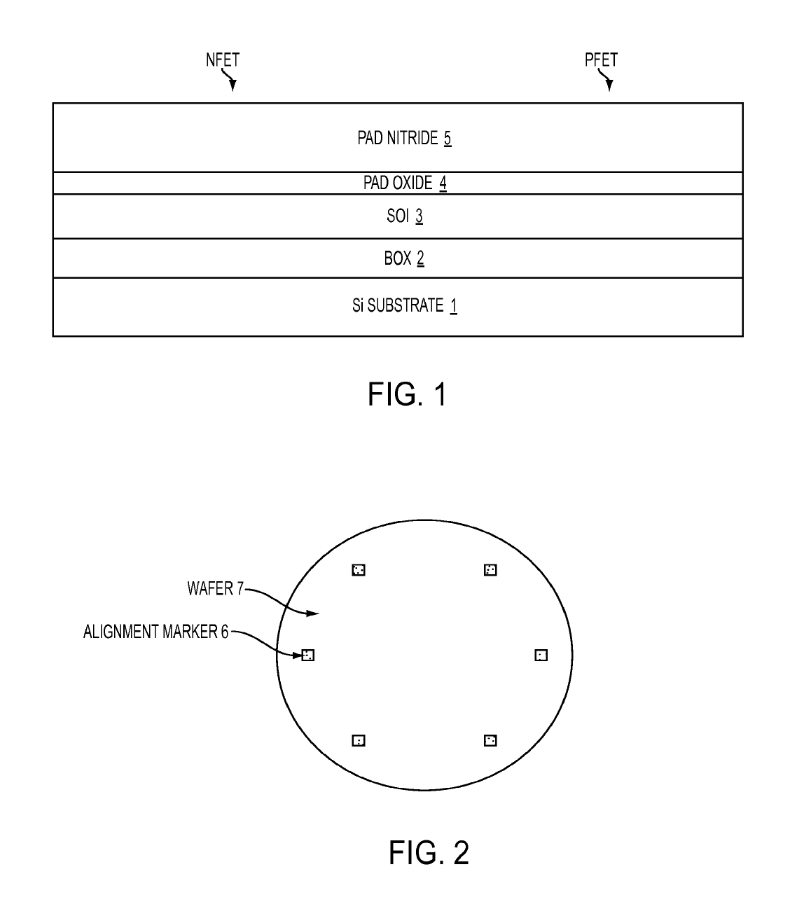

FIGS. 1-6 depict steps used to fabricate CMOS structures according to an embodiment of the present invention. In FIG. 1, a substrate is provided including a silicon substrate 1, a buried oxide layer 2 on top of the silicon substrate, and a silicon layer 3 on top of the buried oxide. The silicon substrate 1 can be a SOI wafer or bulk Si wafer. The SOI wafers could be thick SOI wafer with SOI thickness in the 30-90 nm range or could be thin SOI wafers with SOI thickness in 15-30 nm range. For thick SOI starting wafers, SOI thinning can be done to reduce the SOI thickness down to 15-30 nm range using oxidation and hydrofluoric acid wet etch.

The wafers are then oxidized to create about a 2-10 nanometer thick pad oxide 4. Thermal oxidation of Si-based wafers is typically performed in the temperature range of approximately 700-900° C. and optionally including steam in an oxidation furnace. Conditions can be varied to allow for dry and wet oxide and to vary the thickness of the oxide desired. Typical time ranges are in the range of approximately 1-100 minutes.

An about 10-100 nanometer thick layer of pad nitride 5 is then deposited, leading to the structure shown in FIG. 1. Pad nitride can be deposited, for example, using low-pressure chemical vapor deposition (“LPCVD”), rapid thermal chemical vapor deposition (“RTCVD”), or plasma-enhanced chemical vapor deposition (“PECVD”) processes. Typical temperature ranges for such processes are 700-900° C. for LPCVD and RTCVD and 300-500° C. for PECVD. The time can be varied depending on the desired chemical vapor deposition process and the desired thickness of the nitride. Typical time ranges are in the range of approximately 1-100 minutes. The pad oxide 4 relieves stress between Si and pad nitride. The pad nitride 5 in this case acts as an oxidation mask for selective SOI thinning to be performed later in PFET regions.

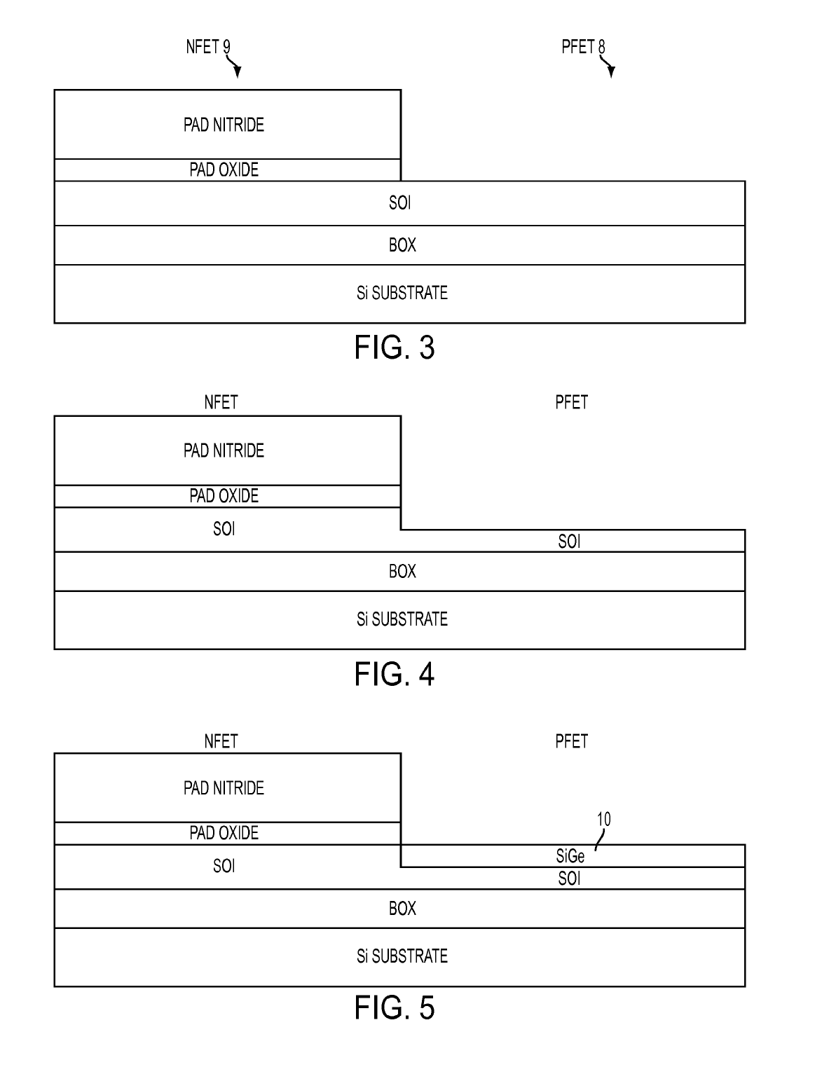

Photolithography, nitride/oxide/Si reactive-ion etch (“RIE”), and photo resist strip are then used to create global alignment markers 6 onto the SOI region. The top view schematic representation of the wafer 7 after alignment marker creation is shown in FIG. 2. Using the global alignment markers 6, photolithography is performed to selectively open up PFET regions 8 in the resist. A nitride/oxide RIE is then performed to expose the SOI 3 in the PFET regions 8 and is followed by resist stripping, leading to the structure shown in FIG. 3.

The PFET regions 8 of the wafer are then selectively thinned down further using oxidation and oxide etch. Typical process conditions for oxidation were previously discussed. The NFET regions 9 will not be thinned down because they are covered with oxide/nitride mask. The SOI thinning target will depend on the Ge content in SiGe to be deposited later so that SiGe does not relax and create dislocations. The Ge content in the SiGe layer ranges from approximately 10-100% depending on the amount of compressive stress desired in the channel. The SiGe layer cannot be too small because not enough stress would be present or too large because the SiGe layer will relax and create dislocations. The typical thickness of the SiGe layer is approximately 2-5 nm. The oxide etch can be done using hydrofluoric acid (HF) wet etch or using RIE chemical oxide removal (COR) process, or any other process that is selective to Si and SiN meaning that it does not etch Si and SiN. RIE COR is very selective to both Si and SiN. Therefore, RIE COR will not result in any additional SOI thinning at PFET regions or thinning of the nitride cover at NFET regions. FIG. 4 shows the wafer after these process steps.

SiGe 10 is then epitaxially deposited, selective to nitride, on the exposed SOI 3 in the PFET regions 8, leading to the structure shown in FIG. 5. The SiGe epitaxy is performed using chemical vapor deposition (CVD″). The temperature of the deposition is in the range of approximately 600-850° C. and depends on the desired Ge % as well as the gas source of Si and Ge used. Non-limiting examples of gases used as a source of Si include: silane (SiH₄), dichlorosilane (SiH₂Cl₂), and silicone tetrachloride (SiCl₄). Non-limiting examples of gases used as a source of Ge include: germane (GeH₄), germane tetrachloride (GeCl₄), and isobutyl germane (C₄H₁₂Ge=(CH₃)₂CHCH₂GeH₃).

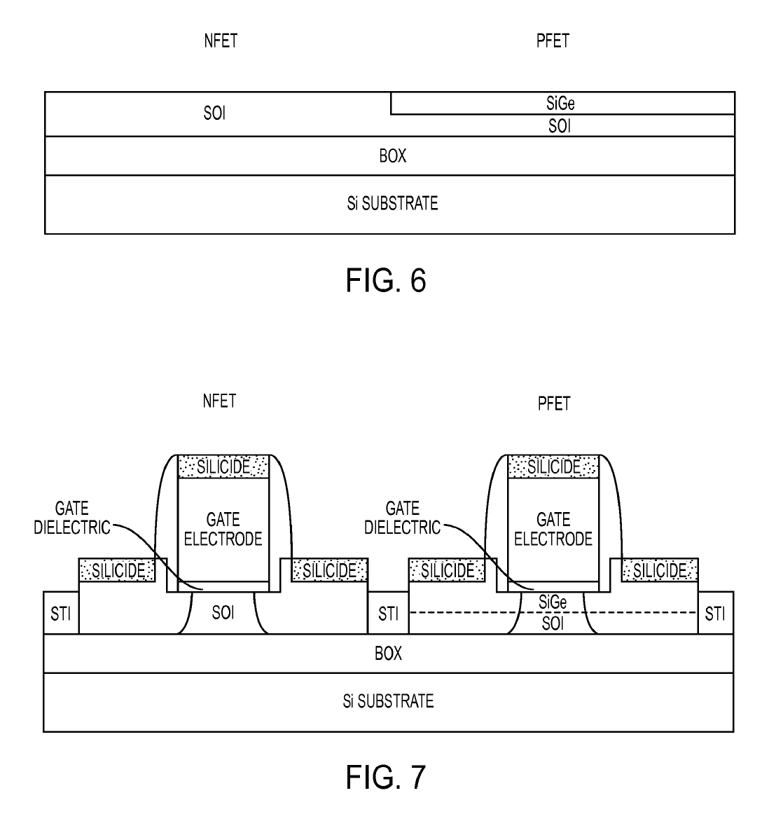

The corner of the NFET/PFET region may have defects but shallow trench isolation (STI) process, to be performed later, removes these defects. The pad nitride 5 and pad oxide 4 layers are then removed using appropriate etchants leading to the structure shown in FIG. 6. Pad nitride 5 can be etched, selective to exposed SiGe, using, for example, hot phosphoric acid. The hot phosphoric acid is typically in the range of 160-180° C. because room-temperature etch rates are too low. The time of the etching process depends on the temperature and the amount of nitride to be etched, but typically would be approximately 10-100 minutes. Pad oxide 4 can be etched, also selective to exposed SiGe, using, for example, hydrofluoric acid (HF). The time of the etching process depends on the concentration of the HF with respect to H₂O in the acid mixture and the amount of oxide to be etched, but typically would be approximately 1-10 minutes.

Following the above-described process, conventional thin SOI processing known in the art can be followed to create the CMOS structure shown in FIG. 7. According to such conventional thin SOI processing, active area definition is performed using the following steps:

a. pad oxidation and pad nitride deposition,

b. active area lithography,

c. active area etch and resist strip,

d. STI liner deposition,

e. STI oxide deposition,

f. optionally, STI oxide densification anneal, and

g. STI CMP stopping on pad nitride.

Then, removal is performed of any remaining STI oxide on active areas and pad nitride using appropriate nitride and oxide etchant, such as, hydrofluoric acid and hot phosphoric acid, respectively. Optional channel SOI implants (also known as well implants) using photography, ion implantation, and resist strip are performed once for NFETs and once for PFETs.

Next, the gate stack is formed using the following steps:

a. pad oxide removal using oxide etchant, such as, hydrofluoric acid,

b. oxidation or high-K dielectric deposition to form the gate dielectric,

c. poly Si deposition or metal-gate followed by poly Si deposition to form the gate electrode,

d. oxidation or deposition of oxide to form poly Si screen oxide for gate ion implants,

e. photolithography, gate ion implantation, and resist strip (performed once for NFETs and once for PFETs),

f. nitride and oxide cap layer deposition (needed for forming raised source/drain using selective epitaxy),

g. gate lithography, and

h. gate etch and resist strip.

Afterward, a disposable spacer is formed using deposition of oxide/nitride or nitride/oxide/nitride layer followed by appropriate RIE. Next, a raised source/drain is formed using:

a. selective epitaxy of intrinsic Si, SiGe, or SiC,

b. photolithography, raised source/drain ion implantation, and resist strip (performed once for NFETs and once for PFETs), and

c. annealing to activate the raised source/drain implants, and to activate and diffuse the gate implants.

The disposable spacer nitride and nitride cap are then removed using a nitride etchant, such as, hot phosphoric acid. Next, optional halo implants (also known as pocket implants) are added using photolithography, ion implantation, and resist strip (performed once for NFETs and once for PFETs) and followed by source/drain extension implants using photolithography, ion implantation, and resist strip (performed once for NFETs and once for PFETs).

Annealing is then performed to activate the source/drain extensions, preferentially a diffusionless anneal, such as, using laser anneal or flash anneal, to avoid the loss of source/drain extension implants into the underlying buried oxide layer. Next, the final spacer formation using oxide liner and nitride deposition are added followed by nitride etch. Finally, self-aligned silicide (also known as salicide) formation is performed using the following steps:

a. oxide removal using oxide etchant, such as, hydrofluoric acid,

b. metal deposition,

c. silicide formation anneal, and

d. selective etch of unreacted metal atop STI oxide and final spacer nitride.

The CMOS structure shown in FIG. 7 is formed after the above-mentioned steps are performed. Subsequently, one can perform conventional CMOS processing starting with barrier nitride deposition up to metal interconnect formation to complete chip fabrication.

The foregoing description illustrates and describes the disclosure. Additionally, the disclosure shows and describes only the preferred embodiment(s) but, as mentioned above, it is to be understood that it is capable to use in various other combinations, modifications, and environments and is capable of changes or modifications within the scope of the invention concepts as expressed herein, commensurate with the above teachings and/or skill or knowledge of the relevant art. The embodiments described herein above are further intended to explain best modes known by the applicants and to enable others skilled in the art to utilize the disclosure in such, or other, embodiments and with the various modifications required by the particular applications or uses thereof. Accordingly, the description is not intended to limit the invention to the form disclosed herein. Also, it is intended to the appended claims be construed to include alternative embodiments.

All publications and patent applications cited in this specification are herein incorporated by reference, and for any and all purposes, as if each individual publication or patent application were specifically and individually indicated to be incorporated by reference. In the event of an inconsistency between the present disclosure and any publications or patent applications incorporated herein by references, the present disclosure controls.

What is claimed is:

1. A CMOS structure comprising:
(A) a NFET channel, wherein the NFET channel material comprises Si;
(B) a PFET channel, wherein the PFET channel material comprises a bottom layer of SiGe and a top layer of Si; and
(C) a buried oxide layer, wherein the buried oxide layer is underneath both the NFET channel and PFET channel.

2. The CMOS structure of claim 1, further comprising:
(D) a silicon substrate underneath the buried oxide layer.

3. The CMOS structure of claim 2, wherein the silicon substrate is selected from the group consisting of SOI wafers or bulk Si wafers.

3. The CMOS structure of claim 1, wherein the thickness of the SiGe layer is approximately 2-5 nm.

4. The CMOS structure of claim 1, wherein the Ge content of the SiGe layer is approximately 10-100%.
